(19) United States
(12) Patent Application Publication
(10) Pub. No.: US 2012/0199867 A1
(43) Pub. Date: Aug. 9, 2012

(54) METHOD FOR ATTACHING AN ELECTRONIC COMPONENT TO A PRODUCT

(75) Inventors: Sigrid Thomas, Saint Martin D'Heres (FR); Victor Thomas, Saint Bonnet De Chavagne (FR)

(73) Assignees: SERIPRESS, Saint Marcellin (FR); Commissariat a I'Energie Atomique et Aux Energies Altematives, Paris (FR)

(21) Appl. No.: 13/266,975

(22) PCT Filed: Apr. 29, 2010
(86) PCT No.: PCT/FR2010/050823

§ 371 Date: Apr. 20, 2012

(30) Foreign Application Priority Data
Apr. 30, 2009 (FR) 0952916

(51) Int. Cl. H01L 33/62; H01L 21/50

(52) U.S. Cl. 257/99; 438/118; 257/E21.499; 257/E33.066

(57) ABSTRACT

An electronic component is attached to a product, using a transfer method involving the use of a transfer sheet including a substrate sheet and at least one transfer layer covering a portion of the front surface of the substrate sheet. The transfer method consists in: placing the transfer layer in contact with the product; applying a pressure against the back surface of the substrate sheet; and finally removing the substrate sheet, said at least one transfer layer remaining affixed to the product. In addition, the attachment method includes a step prior to the transfer method, during which at least one electronic assembly including at least one electronic chip attached to at least one wire is positioned between the product and the substrate sheet, such that at least one portion of each assembly is held in place by a transfer layer following the removal of the substrate sheet.

### FIELD OF THE INVENTION

The present invention relates to a method for attaching an electronic component to a product, and more specifically an attachment method that may be implemented after manufacturing of the product, with no modification or alteration of this product.

### DISCUSSION OF PRIOR ART

The present invention more specifically relates to the attaching of an electronic component comprising at least one electronic chip of small dimensions, the chip dimensions being such that a manual handling thereof is difficult. Such an electronic chip for example is a chip used to manufacture contactless cards known as RFID (“Radio Frequency Identification Data”) cards, which generally have a thickness smaller than one millimeter (generally a few hundreds of micrometers), and a volume smaller than one cubic millimeter.

In the case of contactless cards, the electronic component is formed of an electronic chip connected to an antenna. Such an electronic component is generally attached to a product by means of a sticker. The manufacturing of such a sticker comprises at least a step of antenna manufacturing, followed by a step of positioning of the electronic chip on two conductive pads formed at the same time as the antenna, in line therewith. The chip positioning requires very accurate and expensive devices to position the chips to within a few hundreds, or even a few tens of a micrometer.

In addition to the complexity of the forming of such a sticker, this type of attachment method does not suit all types of products, especially products such as clothes likely to be washed.

An object of the present invention is to provide a method for attaching an electronic component to a product, which is simple and inexpensive to implement.

Another object of the present invention is to provide a method which enables to attach small electronic chips to a product.

Another object of the present invention is to provide a method for attaching an electronic component to a product, which ensures a good hold of the electronic component on the product when used.

To achieve these objects, the present invention provides a method for attaching an electronic component to a product implementing a transfer method using a transfer sheet comprising a support sheet and at least one transferrable layer covering a portion of a front surface of the support sheet, the transfer method comprising placing the transferrable layer in contact with said product, then applying a pressure on the rear surface side of the support sheet, and finally removing the support sheet, said at least one transferrable layer remaining bonded to the product, the method comprising a previous step of positioning at least one electronic assembly comprising at least one electronic chip affixed to at least one wire between the product and the support sheet, so that after removal of the support sheet, at least a portion of each assembly is maintained by a transferrable layer.

According to an embodiment of the above-mentioned method, at least a portion of a wire of each assembly is maintained by a transferrable layer after removal of the support sheet.

According to an embodiment of the above-mentioned method, the method previously comprises a step of partial or total insertion of at least a portion of each assembly into a transferrable layer of the transfer sheet, said at least one electronic assembly being then attached to said transfer sheet before the transfer sheet is placed on said product.

According to an embodiment of the above-mentioned method, said at least one portion of each assembly is totally or partially placed in an adhesive layer of said transferrable layer.

According to an embodiment of the above-mentioned method, said at least a portion of each assembly is placed in contact with a conductive layer of said transferrable layer.

According to an embodiment of the above-mentioned method, the total or partial insertion of said at least a portion of each assembly into a transferrable layer is performed by means of a press.

According to an embodiment of the above-mentioned method, in the transfer process, said transferrable layer is at a temperature greater than its melting temperature.

The present invention further provides a transfer sheet comprising a support sheet and at least one transferrable layer covering a portion of a front surface of the support sheet, said at least one transferrable layer being intended to be placed on a product by means of a press pressing the rear surface side of the support sheet, the transfer sheet further comprising at least one electronic assembly comprising at least one electronic chip affixed on at least one wire, said at least one assembly being arranged so that at least a portion of each assembly is maintained by a transferrable layer.

According to an embodiment of the above-mentioned transfer sheet, at least a portion of a wire of each assembly is maintained by a transferrable layer.

According to an embodiment of the above-mentioned transfer sheet, at least one transferrable layer comprises at least one conductive layer, and at least one portion of a wire of an assembly is in contact with a conductive layer of a transferrable layer.

According to an embodiment of the above-mentioned transfer sheet, at least a portion of a wire of each assembly forms all or part of an antenna.

According to an embodiment of the above-mentioned transfer sheet, at least one chip of an assembly is connected to a portion of a wire forming all or part of an antenna and comprises an electronic circuit capable of transmitting and/or receiving data via the antenna to which it is connected.

According to an embodiment of the above-mentioned transfer sheet, at least one chip of an assembly comprises a light-emitting diode.

According to an embodiment of the above-mentioned transfer sheet, at least one electronic chip of an assembly comprises a sensor.

According to an embodiment of the above-mentioned transfer sheet, said at least one assembly is integrally placed in a transferrable layer.

According to an embodiment of the above-mentioned transfer sheet, the maximum dimension of the electronic chip is smaller than one millimeter and the chip volume is smaller than one cubic millimeter.

According to an embodiment of the above-mentioned transfer sheet, at least one wire on which is attached at least one electronic chip has a conductive portion.

According to an embodiment of the above-mentioned transfer sheet, at least one chip has at least one groove, at least one of said at least one wire on which is attached the considered chip being placed in a groove of this chip.

According to an embodiment of the above-mentioned transfer sheet, at least one conductive pad is placed in a groove of an electronic chip, the conductive pad being in electric contact with a conductive portion of a wire placed in the groove of the considered chip.

According to an embodiment of the above-mentioned transfer sheet, said at least one portion of each assembly maintained by a transferrable layer has a thickness smaller than the thickness of the transferrable layer by which it is maintained.

### BRIEF DESCRIPTION OF THE DRAWINGS

The foregoing and other objects, features, and advantages of the present invention will be discussed in detail in the following non-limiting description of specific embodiments in connection with the accompanying drawings, among which:

FIGS. 1 to 6 are top views of several embodiments of a transfer sheet according to the present invention.

### DETAILED DESCRIPTION

For clarity, the same elements have been designated with the same reference numerals in the different drawings. Further, the different drawings are not to scale.

The attachment method of the present invention aims at attaching an electronic component to a product by implementing a transfer method using a transfer sheet. A transfer sheet comprises a support sheet and at least one transferrable layer covering a portion of a front surface of the support sheet. The transfer method comprises placing the transfer sheet on the product so that the transferrable layer is in contact with the product, then applying a pressure on the rear surface side of the support sheet so that the transferrable layer bonds to the product. Once the transferrable layer bonds to the product, the support sheet is removed.

A transferrable layer of a transfer sheet is conventionally formed of a stacking of a generally colored ink layer and of an adhesive layer. The colored ink layer may in practice be formed of several layers of inks of different colors, as well as of a basic, generally white, ink layer avoiding transparency effects once the transferrable layer bonds to the product.

The support sheet of a transfer sheet is covered with an anti-adherent coating so that, in conditions where the transfer is laid on the product, the transferrable layer adheres more to the product and bonds thereto without separating from the product when the support sheet is removed.

When the transfer method is implemented, means for heating the transferrable layer, as well as a transfer sheet comprising transferrable layers with an adhesive layer having a high melting point, at least equal to 80° C. and preferably greater than 120° C., are preferably used. The heating means are then provided to heat the transferrable layers above their melting point. Such a hot transfer method provides a transferrable layer which is more resistant once on the product, for example, in a washing.

Further, the method of the present invention aims at attaching to a support an electronic component comprising at least one electronic assembly, each electronic assembly comprising at least one electronic chip attached to at least one wire. In the implementation of the attachment method according to the present invention, each assembly is positioned so that after the transfer method has been implemented, at least a portion of each assembly is maintained on the product by a transferrable layer.

According to a first embodiment of the attachment method according to the present invention, at least one electronic assembly is first placed on a product. A transfer method is then implemented by placing a transfer sheet on the product, so that, for each assembly, at least one transferrable layer covers a portion of the considered assembly. Once the transferrable layer(s) of the transfer sheet bond to the product, the support sheet is removed. Each assembly is then maintained on the product by at least one transferrable layer.

According to a second embodiment of the attachment method according to the present invention, a step of partial or total insertion of at least a portion of each assembly in a transferrable layer of a transfer sheet is performed prior to the transfer. This insertion may be performed after the manufacturing of the transfer sheet or during the manufacturing thereof.

An advantage of this second embodiment of the attachment method is that it eases the positioning of each assembly on top or inside of a transferrable layer.

In the following description, “maintained portion” is used to designate all the elements of an electronic assembly intended to be maintained by at least one transferrable layer. All or part of an assembly can thus be maintained by one or several transferrable layers. In other words, a maintained portion of an assembly may comprise all or part of this assembly.

In the case where the insertion is performed after the transfer sheet manufacturing, each assembly may for example be positioned on the transferrable layer(s) and applied a pressure to have the maintained portion of the assembly penetrate into the transferrable layer(s). The adhesive layer in the upper portion of a transferrable layer may advantageously be provided to be sufficiently thick for the entire maintained portion of an assembly to be integrally inserted in this adhesive layer.

In the case, among others, where the adhesive layer is a hot melt adhesive, this adhesive layer may be heated up on insertion of the maintained portion of the assembly or after insertion into the adhesive layer, so that after cooling, the assembly bonds to this adhesive layer.

In the case where the insertion is performed during the transfer sheet manufacturing, the maintained portion of an assembly may for example be placed on top or inside of an intermediate layer forming the transferrable layers other than the final adhesive layer. Such an intermediate layer may for example be a conductive layer, as illustrated hereinafter in relation with embodiments of the present invention. In this case, the maintained portion of an assembly will preferably be covered with at least one layer, for example, the adhesive layer, to provide a good bonding of the assembly to the product on installation thereof.

The application of a pressure during the insertion of the maintained portion of an assembly may advantageously be performed by means of a mechanical press. Further, during or after the insertion, a heating of the transfer sheet may be provided to promote the bonding of the maintained portion of an assembly. This heating may be performed simultaneously to a pressing operation, for example, by using a heating mechanical press.

A type of assembly that may advantageously be used in the present invention is an assembly such as described in patent applications WO2008/025889 and WO2009/013409. Such an assembly uses electronic chips having at least one groove on one of their surfaces. One or several chips are then attached to one or several wires, each wire being placed in a groove. The attaching of the chip on the wire, or conversely, is provided in each groove by mechanical means (clamping, latch union . . . ) and/or by adhesive means.

Such a method enables to design assemblies having a small thickness. Indeed, it is possible to attach chips having a thickness of a few hundreds of micrometers, typically from 200 to 600 micrometers, to wires having a diameter ranging from 50 to 300 micrometers.

Generally, each assembly comprises at least one support wire having the function of enabling to easy manipulate the assembly. To make the positioning of an assembly easier, on implementing the method of the invention, an assembly comprising at least two support wires will preferably be used, each electronic chip being attached to at least two support wires attached to different points of the chip. In the case where the assembly used corresponds to the type of assembly described in the above-mentioned patent applications, two support wires may for example be placed in grooves formed in opposite lateral surfaces of each electronic chip.

An advantage of the method of the present invention is that it enables to easily manipulate electronic chips due to the use of at least one support wire. The method of the present invention enables to manually handle small electronic chips having a maximum dimension smaller than one millimeter.

Further, each assembly may comprise wires having another function than being a support wire. Such a wire may for example be a conductive wire intended to form an antenna connected to an electronic chip or a power supply lead of at least one chip in the assembly or a data transmission bus between chips or between the chips and a device external to the assembly. Advantageously, a wire may fulfill several functions, that is, behave as a support, an antenna, a power supply, in data transmission or other functions.

Another advantage of the method of the present invention is that it enables to form a large number of electronic assemblies capable of having a great variety of functions, as will better appear from the reading of the embodiments of transfer sheets described hereinafter.

In all the embodiments described hereinafter, each transfer sheet comprises a support sheet, shown by a rectangle, covered with at least one transferrable layer shown in grey. Electronic chips are shown as little black squares. The wire(s) to which the chips are attached are shown by black lines.

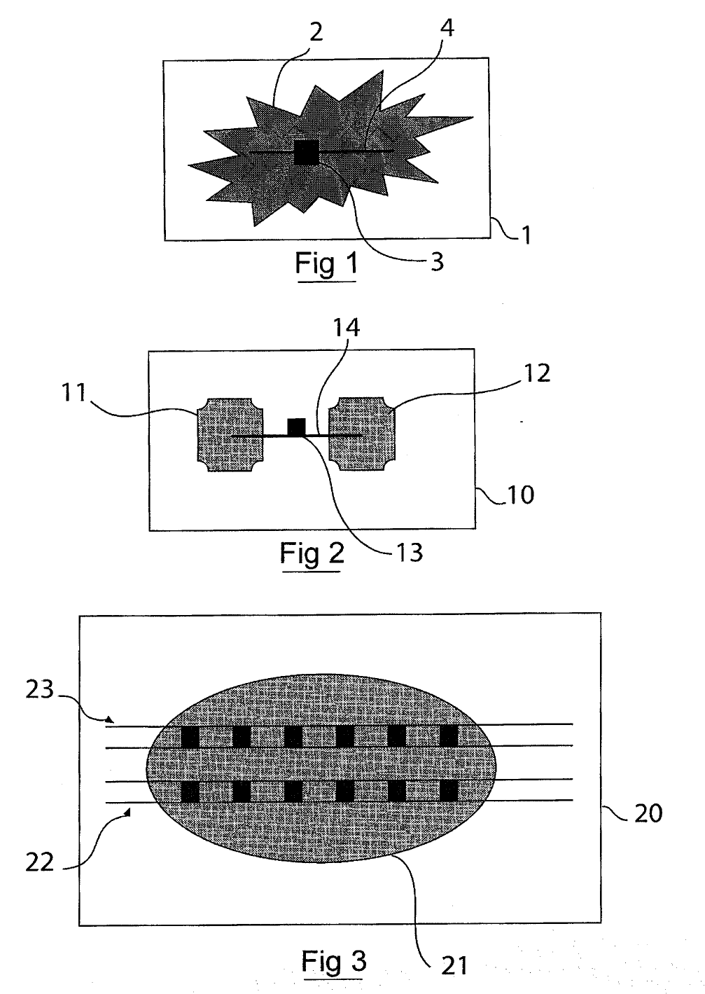

FIG. 1 illustrates a transfer sheet comprising a support sheet 1 covered with a transferrable layer 2. An assembly formed of a chip 3 affixed to a wire 4 is placed in transferrable layer 2. The entire assembly is placed in transferrable layer 2. Thus, when the transferrable layer will be laid on a product, the assembly may be made invisible and/or imperceptible to the touch.

For the assembly to be imperceptible to the touch, the thickness of chip 3 and that of the wire must have the same order of magnitude, preferably lower than the thickness of the transferrable layer. In practice, a transferrable layer of a transfer sheet formed of an assembly of colored ink layers, of a basic white layer, and of an adhesive layer, has a thickness of a few hundreds of micrometers. In the specific case of a transfer sheet comprising a support sheet having a layer of small agglomerated components, such as hair (currently called FLOC) or micro balls, a transferrable layer may have a thickness on the order of one millimeter, or even a few millimeters after laying on the product. Since the thickness of an assembly may reach a few hundreds of micrometers, it is possible to make this assembly imperceptible to the touch once placed on the product.

Further, the assembly may be invisible if the assembly is covered with a sufficiently opaque layer after having been installed. In practice, a transferrable layer comprising a white basic layer is sufficient to make an assembly invisible in standard household lighting conditions.

Further, in the case where an assembly comprises a chip capable of emitting light, such as a light-emitting diode (LED), said chip may be placed under a layer which enables to make the chip invisible when it emits no light and enables to let through, and even better, to diffuse, the light emitted by the chip. The white basic layers generally used in the transfer manufacturing enable to obtain such an effect. Thus, from a small LED, of 300 or 400 micrometers, it is possible to form a light “spot” of several millimeters or even one centimeter.

FIG. 2 illustrates a transfer sheet comprising a support sheet 10 covered with two transferrable layers 11, 12. The transfer layer comprises an assembly formed of a single chip 13 affixed to a wire 14 extending on either side of chip 13. The ends of wire 14 are respectively placed in transferrable layers 11 and 12. Chip 13 is placed above the support sheet, between transferrable layers 11 and 12.

In this example, the chip will be apparent once the transferrable layers have been laid on the product. The assembly will be maintained on the product by the two ends of wires embedded in the transferrable layers. This type of embodiment may be advantageous in the case where it is desired to be able to remove the chip from the product. Such a chip may for example be an RFID chip, which is useful during the product manufacturing, conditioning, transport, and sale period, but becomes useless, or even unwanted, once the product has been sold.

FIG. 3 illustrates a transfer sheet comprising a support sheet 20 covered with a transferrable layer 21. Two electronic assemblies 22 and 23 are placed in transferrable layer 21. Each assembly comprises 6 electronic chips, each attached to two common support wires. The support wires extend beyond the transferrable layer.

An assembly may for example be formed of 6 light-emitting diodes and the two wires provided as conductors. Once the transferrable layers and the assembly have been laid on the product, the conductive support wires may be connected to an electric power supply, the wires being for example respectively connected to ground and to a power supply voltage.

Another assembly may for example be formed of electronic chips of different types, for example, a chip forming a sensor, another chip forming a power recovery device, another chip forming a data processing unit. Such chips may be powered and exchange data via the support wires provided as conductors. It is also possible for the chips to be interconnected by one or several conductive wires, not shown, to separately form the electric power supply of the chips and the data transfer.

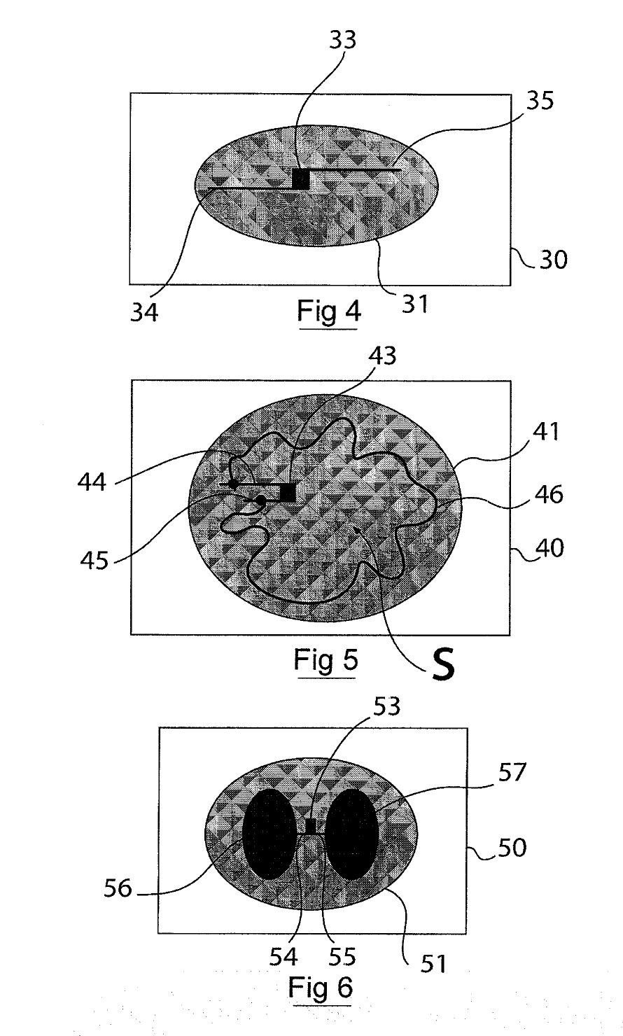

FIG. 4 illustrates a transfer sheet comprising a support sheet 30 covered with a transferrable layer 31 in which is placed an assembly comprising a chip 33 attached to the two wires 34 and 35. Apart from their support function, the wires form elements of a dipole-type antenna. One end of each wire is thus connected to a conductive pad of the electronic chip. The length of the wires is defined according to the wavelength of the electromagnetic signals which are desired to be transmitted or received, as known by those skilled in the art. An electronic chip enabling to transmit and/or to receive electromagnetic signals can thus be easily placed on a product. Such a chip for example is an RFID chip. The two chips forming the antenna may be placed in a line, as shown, or in a portion of a circle, of an oval, or of a spiral. An example of an assembly comprising an RFID chip connected to two conductive wires forming an antenna is described in patent application WO2008/051079.

FIG. 5 illustrates a transfer sheet comprising a support sheet 40 covered with a transferrable layer 41 in which is placed an assembly comprising a chip 43 attached to two conductive wires 44 and 45. A conductive strip 46 is provided in transferrable layer 41. Conductive strip 46 almost closes on itself, thus defining an inner surface area S. Conductive wires 44 and 45 are respectively connected to the ends of conductive strip 46, conductive wire 44 being in electric contact with a first end of the strip and conductive wire 45 being in electric contact with a second end of the strip. The conductive strip and, to a lesser extent, wires 44 and 45, form an antenna capable of being connected to electronic chip 43 by conductive pads placed on the chip and in contact with wires 44 and 45. This type of antenna, having a relatively large surface area S, advantageously enables to remotely supply the chip(s) of the assembly to which they are connected.

The conductive strip of such a transfer sheet may be formed on manufacturing of the different layers forming the transferrable layer. This conductive strip may for example be formed by a screen printing method.

FIG. 6 illustrates a transfer sheet comprising a support sheet 50 covered with a transferrable layer 51 in which is placed an assembly comprising a chip 53 attached to two conductive wires 54 and 55. Transferrable layer 51 further comprises two conductive layers 56 and 57 having an oval shape in the present example. Conductive wire 54 is in contact, on the side of one of its ends, with conductive layer 56. Similarly, conductive wire 55 is in contact, on the side of one of its ends, with conductive layer 57. The other ends of wires 54 and 55 each are in electric contact with a conductive pad of chip 53. Conductive layers 56 and 57 form the main elements of an electromagnetic signal transceiver antenna.

It should be noted that the shape of conductive layers 56 and 57 is an illustration only and is by no means limiting. On the contrary, many other shapes may be used according to the desired type of antenna: operating frequency, bandwidth, quality factor . . . .

An advantage of the method of the present invention is that it enables to form and to simply attach to a product an assembly comprising an electronic chip connected to an antenna.

Other embodiments of a transfer sheet according to the present invention, as well as other methods of application of such a transfer sheet, may be devised by those skilled in the art.

Further, the wires used to form the assemblies may have cross-sections of different shapes. The wire may for example take the form of a thin narrow strip.

To be able to implement the method of the present invention with conventional transfer sheets comprising a colored ink layer covered with an adhesive layer, the wire portions and the chips placed in a transferrable layer must have a sufficiently small width for the entire transferrable layer to properly detach from the support sheet on laying on a product. Indeed, if the width of a wire or of a chip is too large, the portions of the transferable layer covered by the wire or the chip risk remaining attached to the support sheet and not transferring onto the product. To provide a good bonding of each assembly to the product, at least a portion of the assembly will accordingly have to be narrow enough to ensure a good transfer of the transferrable layers intended to maintain this assembly on the product. The maintained portion of each assembly accordingly has a maximum width, parallel to the plane of the support sheet, which is preferably smaller than one millimeter. Various types of electronic chips may be used to form assemblies capable of being attached according to the method of the present invention.

A sensor-type miniature device may for example be provided in an electronic assembly. Especially in the field of game equipment or personal assistance, sensors such as magnetometers, accelerometers, or rate gyros may for example be placed on a clothing item or other. The sensors may also be chemical sensors, for example, sweat sensors. Temperature and pressure sensors may also be used.

A miniature power recovery device may also be provided in an electronic assembly. Such power recovery devices may for example supply electric power to other chips of the assembly by recovering power from a mechanical motion, vibrations, water particle shocks, or by recovering solar or thermal power.

A miniature actuator-type device, which is for example capable of delivering an electric discharge, may further be provided in an electronic assembly.

Further, the method of the present invention may be applied to various types of products such as a clothing item, equipment, a manufactured good, a wall . . . .

An advantage of the method of the present invention is that it enables to simply personalize a piece of equipment by attaching thereto an electronic assembly capable of being specifically defined.

1. A method for attaching an electronic component to a product, implementing a transfer method using a transfer sheet comprising a support sheet and at least one transferrable layer covering a portion of a front surface of the support sheet, the transfer method comprising placing the transferrable layer in contact with said product, then applying a pressure on the rear surface side of the support sheet, and finally removing the support sheet, said at least one transferrable layer remaining bonded to the product, and in that it comprises a step prior to the transfer method, comprising positioning at least one electronic assembly comprising at least one electronic chip attached to at least one wire between the product and the support sheet, so that after removal of the support sheet, at least a portion of each assembly is maintained by a transferrable layer.

2. The attachment method of claim 1, wherein at least a portion of a wire of each assembly is maintained by a transferrable layer after removal of the support sheet.

3. The attachment method of claim 1, previously comprising a step of partial or total insertion of at least a portion of each assembly into a transferrable layer of the transfer sheet, said at least one electronic assembly being then attached to said transfer sheet before placing of the transfer sheet on said product.

4. The attachment method of claim 1, wherein said at least a portion of each assembly is totally or partially placed in an adhesive layer of said transferrable layer.

5. The attachment method of claim 1, wherein at least a portion of each assembly is placed in contact with a conductive layer of said transferrable layer.

6. The attachment method of claim 3, wherein the total or partial insertion of said at least a portion of each assembly into a transferrable layer is performed by means of a press.

7. The attachment method of claim 1, wherein, during the transfer process, said transferrable layer is at a temperature greater than its melting temperature.

8. A transfer sheet comprising a support sheet and at least one transferrable layer covering a portion of a front surface of the support sheet, said at least one transferrable layer being intended to be placed on a product by means of a press pressing on the rear surface side of the support sheet, characterized in that it further comprises at least one electronic assembly comprising at least one electronic chip attached to at least one wire, and in that at least a portion of each assembly is maintained by a transferrable layer.

9. The transfer sheet of claim 8, wherein at least a portion of a wire of each assembly is maintained by a transferrable layer.

10. The transfer sheet of claim 8, wherein said at least one transferrable layer comprises at least one conductive layer, and wherein at least a portion of a wire of an assembly is in contact with a conductive layer of a transferrable layer.

11. The transfer sheet of claim 8, wherein at least a portion of a wire of an assembly forms all or part of an antenna.

12. The transfer sheet of claim 11, wherein at least a chip of an assembly is connected to a portion of a wire forming all or part of an antenna and comprises an electronic circuit capable of transmitting and/or receiving data via the antenna to which it is connected.

13. The transfer sheet of claim 8, wherein at least one chip of an assembly comprises a light-emitting diode.

14. The transfer sheet of claim 8, wherein at least one electronic chip of an assembly comprises a sensor.

15. The transfer sheet of claim 8, wherein said at least one assembly is integrally placed in a transferrable layer.

16. The transfer sheet of claim 8, wherein the maximum dimension of the electronic chip is smaller than one millimeter and the volume of the chip is smaller than one cubic millimeter.

17. The transfer sheet of claim 8, wherein at least one wire to which at least one electronic chip is attached has a conductive portion.

18. The transfer sheet of claim 8, wherein said at least one chip has at least one groove, at least one of said at least one wire on which is attached the considered chip being placed in a groove of this chip.

19. The transfer sheet of claim 17, wherein at least one conductive pad is placed in a groove of an electronic chip, the conductive pad being in electric contact with the conductive portion of a wire placed in the groove of the considered chip.

20. The transfer sheet of claim 19, wherein said at least a portion of each assembly maintained by a transferrable layer has a thickness smaller than the thickness of the transferrable layer by which it is maintained.
